(19) United States
(12) Patent Application Publication
(10) Pub. No.: US 2023/0413597 A1
(43) Pub. Date: Dec. 21, 2023

(54) LIGHT-EMITTING DEVICE

(71) Applicants: Pioneer Corporation, Bunkyo-ku, Tokyo (JP); Tohoku Pioneer Corporation, Tendo-shi, Yamagata (JP)

(72) Inventors: Jun TAKAHASHI, Yonezawa-shi, Yamagata (JP); Noriaki WAKI, Yonezawa-shi, Yamagata (JP); Shinji NAKAJIMA, Yonezawa-shi, Yamagata (JP)

(21) Appl. No.: 18/271,142

(22) PCT Filed: Jan. 12, 2022
(86) PCT No.: PCT/JP2022/000709

§ 371 Date: Jul. 6, 2023

(30) Foreign Application Priority Data
Jan. 15, 2021 (JP) 2021-005109

(51) Int. Cl. H10K 50/826; H10K 50/84

(52) U.S. Cl. CPC H10K 50/826; H10K 2102/20; H10K 50/846

(57) ABSTRACT

A light-emitting device (10) includes a substrate (100), a first electrode (110), an organic layer (120), a plurality of first metal-containing layers (132), a metal compound-containing layer (134), and a second metal-containing layer (136). The first electrode (110) is located over the substrate (100), and has a light transmitting property. The organic layer (120) is located over the first electrode (110). The plurality of first metal-containing layers (132) are located over the organic layer (120), and has a light shielding property. The metal compound-containing layer (134) covers the plurality of first metal-containing layers (132), and has a light transmitting property. The second metal-containing layer (136) covers the metal compound-containing layer (134), and has a light transmitting property.

### TECHNICAL FIELD

The present invention relates to a light-emitting device.

### BACKGROUND ART

In recent years, various kinds of organic light emitting diode (OLED) having a light transmitting property have been developed. For example, in Patent Document 1, a light-emitting device including a first electrode, an organic layer, and a plurality of second electrodes which are arranged in a stripe pattern and have a light shielding property is described. A region of the light-emitting device located between second electrodes which are adjacent to each other is a light-transmitting unit transmitting 20 light from outside. The light-emitting device has a light transmitting property due to the light-transmitting unit.

### RELATED DOCUMENT

### Patent Document

Patent Document 1: Japanese Unexamined Patent Application Publication No. 2013-149376

### SUMMARY OF THE INVENTION

### Technical Problem

For example, as described in Patent Document 1, in a case where a plurality of second electrodes are arranged being separated from each other, such as a case where the plurality of second electrodes are arranged in a stripe pattern or the like, a first metal-containing layer which serves as each of the second electrodes may be covered by a second metal-containing layer. In a case where a thickness of the second metal-containing layer is relatively thin, it is possible to supply voltage to each first metal-containing layer through the second metal-containing layer while maintaining a light transmitting property of the light-emitting device. However, in a case where the thickness of the second metal-containing layer is relatively thin, there may be a case where flatness of the second metal-containing layer is not secured due to that metals contained in the second metal-containing layer are separated from each other in a shape of a plurality of islands.

An example of a problem to be solved by the present invention is to secure flatness of a second metal-containing layer covering a plurality of first metal-containing layers which are arranged being separated from each other.

### Solution to Problem

The invention described in claim 1 is a light-emitting device including:
a substrate,
a first electrode having a light transmitting property located over the substrate,
an organic layer located over the first electrode,
a plurality of first metal-containing layers having a light shielding property located over the organic layer,
a metal compound-containing layer having a light transmitting property covering the plurality of first metal-containing layers, and
a second metal-containing layer having a light transmitting property covering the metal compound-containing layer.

### BRIEF DESCRIPTION OF THE DRAWINGS

FIG. 1 is a cross sectional schematic view of a light-emitting device according to an embodiment.

FIG. 2 is a view showing a first example of a layout of a plurality of first metal-containing layers when viewed from a first side or a second side of the light-emitting device.

FIG. 3 is a view showing a second example of a layout of a plurality of the first metal-containing layers when viewed from the first side or the second side of the light-emitting device.

### DESCRIPTION OF EMBODIMENTS

Hereinafter, embodiments of the present invention will be described with reference to the drawings. In all the drawings, similar components are denoted by the same reference numerals, and the description thereof will be omitted as appropriate.

In the present specification, the expression “A is located over B” may mean that, for example, A is located directly over B without another element (for example, layer) located between A and B, or may mean that another element (for example, layer) is partly or wholly located between A and B. In addition, an expression indicating a direction such as “top”, “bottom”, “left”, “right”, “front”, and “rear” or the like is basically used in combination with a direction of a drawing, and it is not limited to be interpreted for, for example, a direction of the use of an invention described in the present specification.

In the present specification, unless otherwise noted, the expression “A and B overlap” means that at least a part of A occupies the same area as at least a part of B in an image projected from a certain direction. At this time, a plurality of elements may be in contact with each other, or may be separated from each other.

In the present specification, an anode indicates an electrode which injects an electron hole into a layer (for example, organic layer) including a light-emitting material, and a cathode indicates an electrode which injects an electron into a layer including the light-emitting material. Further, the expressions “anode” and “cathode” may mean other wordings such as “electron hole injection electrode” and “electron injection electrode”, or “positive electrode” and “negative electrode” or the like.

“Light-emitting device” in the present specification includes a device including a light-emitting element such as a display or illumination or the like. Further, there may be a case where a wiring directly, indirectly, or electrically connected to a light-emitting element, an integrated circuit (IC), or a housing or the like is also included in “light-emitting device”.

In the present specification, “connection” indicates a state in which a plurality of elements are being connected regardless of whether they are directly or indirectly connected. For example, a case where the plurality of elements are connected with an adhesive or a connecting member therebetween may also be expressed simply as “a plurality of elements are connected”. Further, a case where a member which is capable of supplying or transmitting current, voltage, or electrical potential exists between the plurality of elements and “the plurality of elements are electrically connected” may also be expressed simply as “a plurality of elements are connected”.

In the present specification, unless otherwise noted, expressions such as “first, second, A, B, (a), (b)” or the like are intended to distinguish an element, and an essence, an order, a sequence, a quantity, or the like of the element is not limited by the expression.

In the present specification, each member and each element may be singular, or plural. However, when “singular” or “plural” is clear in a context, it is not limited to this.

In the present specification, unless otherwise noted, a meaning of the expression “A includes B” is not limited to that A is configured only with B, but that A can be configured with elements other than B.

In the present specification, unless otherwise noted, “section” means a surface which appears when a light-emitting device is cut in a direction of a pixel or a light-emitting material or the like being laminated.

In the present specification, expressions such as “does not have”, “does not include”, and “is not located” or the like may mean that a certain element is completely excluded or that a certain element exists to a degree at which the element does not have a technical effect.

In the present specification, unless otherwise noted, the expression “A covers B” may mean that A is in contact with B without another element (for example, layer) located between A and B, or may mean that another element (for example, layer) is partly or wholly located between A and B.

In the present specification, “A has a light transmitting property” means that an average transmittance of A in a wavelength band of equal to or higher than 400 nm and equal to or lower than 700 nm is, for example, equal to or greater than 50%.

In the present specification, “A has a light shielding property” means that the average transmittance of A in the wavelength band of equal to or higher than 400 nm and equal to or lower than 700 nm is, for example, less than 50%.

In the present specification, unless otherwise noted, the expression “A contains a as a main component” means that an amount of a included in A is equal to or greater than 75 parts by mass with respect to the total mass of 100 parts by mass.

In the present specification, unless otherwise noted, “a metal” means not only a metal composed of a single metal element, but also an alloy.

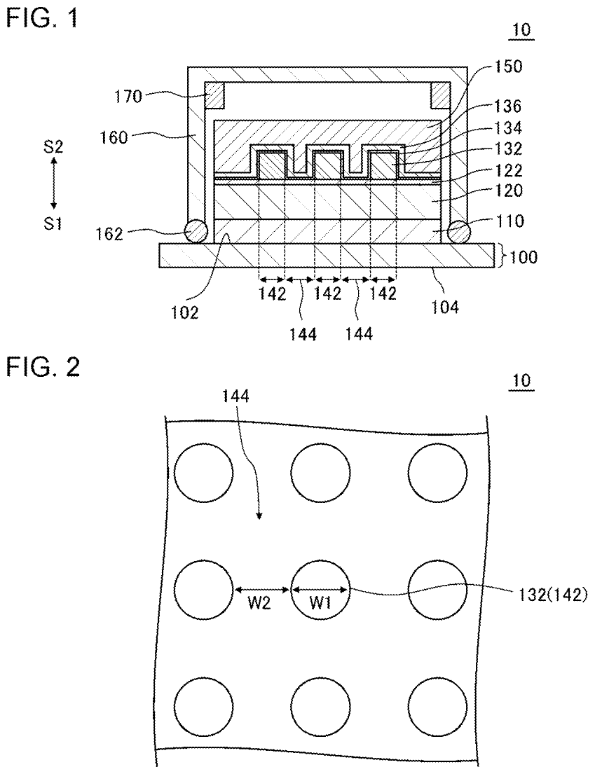

FIG. 1 is a cross sectional schematic view of a light-emitting device 10 according to an embodiment.

The light-emitting device 10 includes a substrate 100, a first electrode 110, an organic layer 120, an electron injection layer 122, a plurality of first metal-containing layers 132, a metal compound-containing layer 134, a second metal-containing layer 136, a cap layer 150, a sealing unit 160, and a desiccant 170. The substrate 100 includes a first surface 102 and a second surface 104. The first electrode 110, the organic layer 120, the electron injection layer 122, the plurality of first metal-containing layers 132, the metal compound-containing layer 134, the second metal-containing layer 136, the cap layer 150, the sealing unit 160, and the desiccant 170 are located on the first surface 102 side. The second surface 104 is located on the side opposite to the first surface 102.

In FIG. 1, a first side S1 shown by an arrow indicates a side of the light-emitting device 10 on which the organic layer 120 is located, opposite to a side on which the plurality of first metal-containing layers 132 are located. A second side S2 shown by an arrow indicates the side of the light-emitting device 10 on which the plurality of first metal-containing layers 132 are located, opposite to the side on which the organic layer 120 is located. Both of the arrows showing the first side S1 and the second side S2 indicate a direction perpendicular to the first surface 102 or the second surface 104.

The substrate 100 has a light transmitting property. The substrate 100 may be single-layered or multi-layered. A thickness of the substrate 100 is, for example, equal to or greater than 10 μm and equal to or less than 1,000 μm. The substrate 100 is, for example, a glass substrate. The substrate 100 may be a resin substrate containing an organic material (for example, polyethylene naphthalate (PEN), polyether sulphone (PES), polyethylene terephthalate (PET), or polyimide). In a case where the substrate 100 is a resin substrate, an inorganic barrier layer (for example, SiN or SiON) may be located over at least one of the first surface 102 and the second surface 104.

The first electrode 110 has a light transmitting property. The first electrode 110 is located over the first surface 102. The first electrode 110 functions as an anode. In one example, the first electrode 110 includes an oxide semiconductor such as indium tin oxide (ITO), indium zinc oxide (IZO), indium tungsten zinc oxide (IWZO), zinc oxide (ZnO), or indium galium zinc oxide (IGZO) or the like. Alternatively, the first electrode 110 may include a metal such as pure silver, or a silver alloy or the like. In this example, a thickness of the first electrode 110 is thin enough for the first electrode 110 to have the light transmitting property.

The organic layer 120 has a light transmitting property. The organic layer 120 is located over the first electrode 110. The organic layer 120 includes a light-emitting layer. The light-emitting layer emits light by organic electroluminescence (EL). The organic layer 120 may appropriately include another layer, such as a hole injection layer (HIL), a hole transport layer (HTL), or an electron transport layer (ETL).

The electron injection layer 122 is located over the organic layer 120. The electron injection layer 122 includes an alkali metal compound such as Li₂O or the like. Supposing that the electron injection layer 122 includes a metal such as an alkali metal such as Li or the like, or an alkaline earth metal such as Ca or the like instead of the alkali metal compound, in comparison with a case where the electron injection layer 122 includes the alkali metal compound, an electron is easily injected to the organic layer 120 in a light-transmitting unit 144, which is to be described later, via the electron injection layer 122 depending on the relationship between the work function of the material of each layer. Thus, it is more preferable that the electron injection layer 122 includes the alkali metal compound than the metal. Note that, the electron injection layer 122 is not required to be provided. In addition, the electron injection layer 122 may include the metal.

As described in detail later, the plurality of first metal-containing layers 132, a metal compound-containing layer 134, and a second metal-containing layer 136 are located over the electron injection layer 122.

The cap layer 150 covers the second metal-containing layer 136. The cap layer 150 includes, for example, an organic material. This organic material may be the same as an organic material included in the organic layer 120.

The sealing unit 160 seals a laminate including the first electrode 110, the organic layer 120, the electron injection layer 122, the plurality of first metal-containing layers 132, the metal compound-containing layer 134, the second metal-containing layer 136, and the cap layer 150. In an example shown in FIG. 1, the sealing unit 160 is a sealing can installed over the first surface 102 of the substrate 100 via an adhesive layer 162. Further, a space between the sealing unit 160 and the laminate described above is hollow. However, the sealing unit 160 is not limited to that of the example shown in FIG. 1. For example, the sealing unit 160 may be a sealing layer covering the laminate described above. For example, the sealing layer includes an inorganic insulating material such as alumina (Al₂O₃), titania (TiO₂) or the like formed by atomic layer deposition (ALD).

The desiccant 170 is positioned within the area sealed with the sealing unit 160. In the example shown in FIG. 1, the desiccant 170 is installed on the surface of the sealing unit 160 facing the area sealed with the sealing unit 160.

Next, details of the plurality of first metal-containing layers 132, the metal compound-containing layer 134, and the second metal-containing layer 136 are explained.

The plurality of first metal-containing layers 132 are located over the electron injection layer 122. Each of the first metal-containing layers 132 has the light shielding property, specifically, light reflectivity.

The first metal-containing layer 132 contains the metal as a main component. In one example, the first metal-containing layer 132 includes aluminum such as pure aluminum or an aluminum alloy or the like. Note that the metal included in the first metal-containing layer 132 is not limited to that of the one example.

A thickness of the first metal-containing layer 132 is not particularly limited, however, the thickness may be equal to or greater than 50 nm and equal to or less than 300 nm.

The first metal-containing layer 132 performs the function of assisting an electron to be injected to the organic layer 120. The work function of the metal included in the first metal-containing layer 132 is, for example, larger than a lowest unoccupied molecular orbital (LUMO) of an electron transport material included in the organic layer 120, and smaller than the work function of a metal included in the second metal-containing layer 136. In one example, the work function of the metal included in the first metal-containing layer 132 may be equal to or greater than 3.5 eV and equal to or less than 4.4 eV. Note that the work function of the metal included in the first metal-containing layer 132 is not limited to that of the one example.

The plurality of first metal-containing layers 132 define a plurality of the light-emitting units 142 and the light-transmitting unit 144 in the light-emitting device 10.

Each of the light-emitting units 142 includes a portion of the first electrode 110, a portion of the organic layer 120, and a portion of the electron injection layer 122, which overlap each of the first metal-containing layers 132, and the first metal-containing layer 132 in the direction perpendicular to the first surface 102 or the second surface 104. Light generated in the organic layer 120 in the light-emitting unit 142 and emitted to the first electrode 110 is transmitted through the first electrode 110 and the substrate 100, and emitted from the first side S1. The light generated in the organic layer 120 in the light-emitting unit 142 and emitted to the first metal-containing layer 132 is reflected by the first metal-containing layer 132, transmitted through the first electrode 110 and the substrate 100, and emitted from the first side S1.

The light-transmitting unit 144 is located between light-emitting units 142 adjacent to each other along a direction parallel to the first surface 102 or the second surface 104. No member having a light shielding property is provided in the light-transmitting unit 144 and any region of the light-emitting device overlapping the light-transmitting unit 144 in the direction perpendicular to the first surface 102 or the second surface 104. Therefore, light from outside of the light-emitting device 10 can be transmitted from one of the first side S1 and the second side S2 to the other. Thereby, the light-emitting device 10 has the light transmitting property.

The metal compound-containing layer 134 covers the plurality of first metal-containing layers 132. The metal compound-containing layer 134 has a light transmitting property.

The metal compound-containing layer 134 contains a metal compound such as a metal oxide, or a metal sulfide or the like as a main component. In one example, the metal compound-containing layer 134 includes at least one selected from a group consisting of molybdenum oxide such as molybdenum oxide (VI), or molybdenum oxide (IV) or the like, tungsten oxide such as tungsten oxide (VI) or the like, vanadium oxide such as vanadium oxide (V) or the like, titanium oxide such as titanium oxide (IV) or the like, tantalum oxide such as tantalum oxide (V) or the like, rhenium oxide such as rhenium oxide (VI) or the like, and zinc sulfide. From the viewpoint of versatility, a function, price, and availability or the like, the metal compound-containing layer 134 preferably includes the molybdenum oxide (VI). Note that the metal compound included in the metal compound-containing layer 134 is not limited to that of the one example. For example, even a metal compound having an oxidation number which is different from the oxidation numbers exemplified above can be utilized in so far as the metal compound is chemically stable. Further, from a viewpoint of the work function, for example, a metal compound having a work function which is close to the work function of the molybdenum oxide (VI) can be utilized.

In one example, the work function of the metal compound included in the metal compound-containing layer 134 may be greater than 5.7 eV. Note that the work function of the metal compound included in the metal compound-containing layer 134 is not limited to that of the one example.

In a case where the metal compound-containing layer 134 is provided, in comparison with a case where the metal compound-containing layer 134 is not provided, it is possible to improve flatness of the second metal-containing layer 136 while making a thickness of the second metal-containing layer 136 thin enough to secure a light transmitting property of the second metal-containing layer 136. In a case where the metal compound-containing layer 134 is not provided, at an early stage of deposition, such as vapor deposition or the like, of the metal included in the second metal-containing layer 136, that is, at a stage when the amount of deposited metal included in the second metal-containing layer 136 is relatively small, a plurality of islands separated from one another are formed from a nucleus of the metal included in the second metal-containing layer 136. In addition, as the amount of deposited metal included in the second metal-containing layer 136 increases, the plurality of islands are connected to each other, thus forming a continuous layer. Thus, in a state in which the metal compound-containing layer 134 is not provided, even if it is attempt to form the second metal-containing layer 136 that is thin enough to secure the light transmitting property of the second metal-containing layer 136 over the electron injection layer 122 and the plurality of first metal-containing layers 132, the metal included in the second metal-containing layer 136 would not form a continuous layer and be separated from each other in a shape of a plurality of islands. Further, in the state in which the metal compound-containing layer 134 is not provided, when the amount of deposited metal included in the second metal-containing layer 136 is enough for the metal included in the second metal-containing layer 136 to form the continuous layer, it is not possible to make the thickness of the second metal-containing layer 136 thin enough to secure the light transmitting property of the second metal-containing layer 136. In contrast, in a case where the second metal-containing layer 136 is formed over the electron injection layer 122 and the plurality of first metal-containing layers 132 with the metal compound-containing layer 134 interposed therebetween, even when the amount of deposited metal included in the second metal-containing layer 136 is not enough for the metal included in the second metal-containing layer 136 to form the continuous layer without the metal compound-containing layer 134 provided, the metal included in the second metal-containing layer 136 can form the continuous layer by chemical interaction between the metal compound included in the metal compound-containing layer 134 and the metal included in the second metal-containing layer 136. That is, the metal compound-containing layer 134 functions as an anchor of the second metal-containing layer 136.

In a case where the metal compound-containing layer 134 is provided, in comparison with a case where the metal compound-containing layer 134 is not provided, it is possible to inhibit light from being generated from the organic layer 120 in the light-transmitting unit 144. Specifically, supposing that the second metal-containing layer 136 is provided over the electron injection layer 122 and the plurality of first metal-containing layers 132 in a state in which the metal compound-containing layer 134 is not provided, light may be generated from the organic layer 120 in the light-transmitting unit 144 when an electron is injected to the organic layer 120 from the second metal-containing layer 136 in the light-transmitting unit 144 through the electron injection layer 122. In contrast, in a case where the metal compound-containing layer 134 is provided, it is possible for the metal compound-containing layer 134 to inhibit an electron from being injected to the organic layer 120 from the second metal-containing layer 136 in the light-transmitting unit 144. Therefore, in a case where the metal compound-containing layer 134 is provided, in comparison with a case where the metal compound-containing layer 134 is not provided, it is possible to inhibit light from being generated from the organic layer 120 in the light-transmitting unit 144.

In one example, the thickness of the metal compound-containing layer 134 may be equal to or greater than 10 Å and equal to or less than 50 Å. In a case where the thickness of the metal compound-containing layer 134 is within the range of the one example, in comparison with a case where the thickness of the metal compound-containing layer 134 is smaller than the lower limit of the range of the one example, it is possible for the metal compound-containing layer 134 to inhibit the electron from being injected to the organic layer 120 from the second metal-containing layer 136 in the light-transmitting unit 144. Further, in a case where the thickness of the metal compound-containing layer 134 is within the range of the one example, in comparison with a case where the thickness of the metal compound-containing layer 134 is larger than the upper limit of the range of the one example, it is possible to inhibit the metal compound-containing layer 134 from obstructing an injection of the electron to the first metal-containing layer 132 from the second metal-containing layer 136. Note that the thickness of the metal compound-containing layer 134 is not limited to that of the one example.

The second metal-containing layer 136 covers the metal compound-containing layer 134. The second metal-containing layer 136 has a light transmitting property.

The second metal-containing layer 136 contains the metal as a main component. In one example, the second metal-containing layer 136 includes at least one selected from a group consisting of silver such as pure silver or silver alloy or the like, gold such as pure gold or a gold alloy or the like, and copper such as pure copper or a copper alloy or the like. From the viewpoint of the light transmitting property of the second metal-containing layer 136, the second metal-containing layer 136 preferably includes the silver. Note that the metal included in the second metal-containing layer 136 is not limited to that of the one example.

In one example, the work function of the metal included in the second metal-containing layer 136 is larger than 4.5 eV. Note that the work function of the metal included in the second metal-containing layer 136 is not limited to that of the one example.

In one example, the thickness of the second metal-containing layer 136 may be equal to or greater than 6.0 nm and equal to or less than 15 nm. In a case where the thickness of the second metal-containing layer 136 is within the range of the one example, in comparison with a case where the thickness of the second metal-containing layer 136 is smaller than the lower limit of the range of the one example, it is possible to inhibit the metal included in the second metal-containing layer 136 from being separated from each other in the shape of the plurality of islands. Further, in a case where the thickness of the second metal-containing layer 136 is within the range of the one example, in comparison with a case where the thickness of the second metal-containing layer 136 is smaller than the lower limit of the range of the one example, it is possible to increase conductivity of the second metal-containing layer 136. Further, in a case where the thickness of the second metal-containing layer 136 is within the range of the one example, in comparison with a case where the thickness of the second metal-containing layer 136 is larger than the upper limit of the range of the one example, it is possible to increase the light transmitting property of the second metal-containing layer 136. Note that the thickness of the second metal-containing layer 136 is not limited to that of the one example.

As combinations of materials included in the first metal-containing layer 132, the metal compound-containing layer 134, and the second metal-containing layer 136, from the viewpoint of a relationship or the like of the work function of each material, the combination of Al for the first metal-containing layer 132, MoO 3 for the metal compound-containing layer 134 and, and Ag for the second metal-containing layer 136 is exemplified.

FIG. 2 is a view showing a first example of a layout of the plurality of first metal-containing layers 132 when viewed from the first side S1 or the second side S2 of the light-emitting device 10.

A plan layout of FIG. 2 is explained with reference to FIG. 1.

When viewed from the direction perpendicular to the first surface 102 or the second surface 104, each of the plurality of first metal-containing layers 132 is surrounded by the light-transmitting unit 144. In other words, each of the plurality of first metal-containing layers 132 is in the shape of the islands which are separated from each other with the light-transmitting unit 144 interposed therebetween. Supposing that the plurality of first metal-containing layers 132 are arranged in a stripe pattern, visibility of the light transmitting property of the light-emitting device 10 when viewed from the first side S1 or the second side S2 can be affected depending on the orientation of the light-emitting device 10 such as whether the plurality of first metal-containing layers 132 are aligned in a vertical direction or a lateral direction or the like when viewed from the first side S1 or the second side S2. In contrast, in a case where each of the plurality of first metal-containing layers 132 is surrounded by the light-transmitting unit 144, in comparison with a case where the plurality of first metal-containing layers 132 are arranged in the stripe pattern, it is possible to inhibit an effect on the visibility of the light transmitting property of the light-emitting device 10 due to the orientation of the light-emitting device 10 when viewed from the first side S1 or the second side S2.

In addition, in the present embodiment, it is possible to supply voltage to the plurality of first metal-containing layers 132 through the second metal-containing layer 136 which covers the plurality of first metal-containing layers 132. Supposing that the voltage is supplied to each of the first metal-containing layers 132 through the wiring extracted from each of the first metal-containing layers 132, the visibility of the light transmitting property of the light-emitting device 10 can be affected by the wiring extracted from each of first metal-containing layers 132. In contrast, in the present embodiment, the wiring extracted from the first metal-containing layer 132 need not be provided. Therefore, it is possible to inhibit an effect of the wiring extracted from the first metal-containing layer 132 on the visibility of the light transmitting property of the light-emitting device 10.

The plurality of first metal-containing layers 132 are regularly arranged when viewed from the direction perpendicular to the first surface 102 or the second surface 104. Specifically, the plurality of first metal-containing layers 132 are arranged in a square lattice shape. Thereby, a pattern of the plurality of first metal-containing layers 132 has translational symmetry. Note that the plurality of first metal-containing layers 132 may be arranged in a lattice shape which is different from the square lattice shape, for example, a rectangular lattice shape. In a case where the plurality of first metal-containing layers 132 are regularly arranged when viewed from the direction perpendicular to the first surface 102 or the second surface 104, in comparison with a case where the plurality of first metal-containing layers 132 are irregularly arranged when viewed from the direction perpendicular to the first surface 102 or the second surface 104, it is possible to make a distribution of luminance of the plurality of light-emitting units 142 when viewed from the first side S1 and a distribution of the light-transmitting unit 144 uniform. Note that the plurality of first metal-containing layers 132 may be irregularly arranged when viewed from the direction perpendicular to the first surface 102 or the second surface 104.

A shape of each of the first metal-containing layers 132 is a circle when viewed from the direction perpendicular to the first surface 102 or the second surface 104. However, the shape of each of the first metal-containing layers 132 is not limited to that of this example. For example, when viewed from the direction perpendicular to the first surface 102 or the second surface 104, the shape of each of the first metal-containing layers 132 may be a polygon such as a triangle, a quadrangle, a pentagon, a hexagon, or an octagon or the like, or an ellipse. Further, when viewed from the direction perpendicular to the first surface 102 or the second surface 104, the shape of each of the first metal-containing layers 132 may be the same as each other, or may be different from each other.

In one example, when viewed from the direction perpendicular to the first surface 102 or the second surface 104, a width W1 of the first metal-containing layer 132 may be equal to or greater than mm and equal to or less than 1.0 mm. In a case where the width W1 is within the range of the one example, in comparison with a case where the width W1 is smaller than the lower limit of the range of the one example, it is possible to increase the total light-emitting area of the plurality of light-emitting units 142. Further, in a case where the width W1 is within the range of the one example, in comparison with a case where the width W1 is larger than the upper limit of the range of the one example, it is possible to increase the light transmitting property of the light-emitting device 10. Note that the width W1 is not limited to that of the one example.

In one example, when viewed from the direction perpendicular to the first surface 102 or the second surface 104, a width W2 of the light-transmitting unit 144 between the first metal-containing layers 132 adjacent to each other may be equal to or greater than 0.050 mm and equal to or less than 2.0 mm. In a case where the width W2 is within the range of the one example, in comparison with a case where the width W1 is smaller than the lower limit of the range of the one example, it is possible to increase the light transmitting property of the light-emitting device 10. Further, in a case where the width W2 is within the range of the one example, in comparison with a case where the width W1 is larger than the upper limit of the range of the one example, it is possible to increase the total light-emitting area of the plurality of light-emitting units 142. Note that the width W2 is not limited to that of the one example.

In one example, when viewed from the direction perpendicular to the first surface 102 or the second surface 104, the ratio W1/W2 of the width W1 to the width W2 may be equal to or greater than 0.50 and equal to or less than 1.7. In a case where the ratio W1/W2 is within the range of the one example, in comparison with a case where the ratio W1/W2 is smaller than the lower limit of the range of the one example, it is possible to increase the total light-emitting area of the plurality of light-emitting units 142. Further, in a case where the ratio W1/W2 is within the range of the one example, in comparison with a case where the ratio W1/W2 is larger than the upper limit of the range of the one example, it is possible to increase the light transmitting property of the light-emitting device 10. Note that the ratio W1/W2 is not limited to that of the one example.

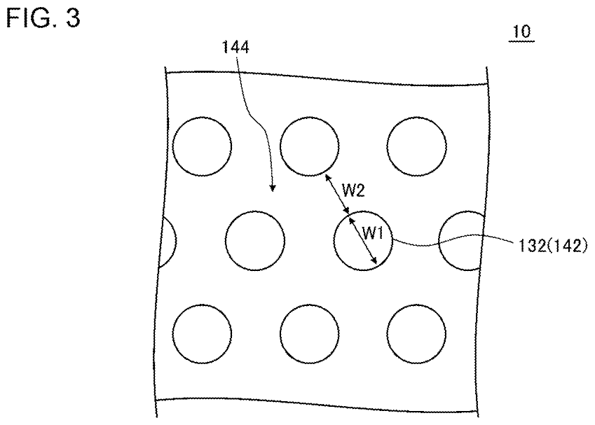

FIG. 3 is a view showing a second example of the layout of the plurality of first metal-containing layers 132 when viewed from the first side S1 or the second side S2 of the light-emitting device 10. The example shown in FIG. 3 is the same as the example shown in FIG. 2, except for the following points.

When viewed from the direction perpendicular to the first surface 102 or the second surface 104, the plurality of first metal-containing layers 132 are arranged in a rhombic lattice shape. In the example shown in FIG. 3 also, in comparison with a case where the plurality of first metal-containing layers 132 are arranged in the stripe pattern, it is possible to inhibit an effect on the visibility of the light transmitting property of the light-emitting device 10 due to the orientation of the light-emitting device 10 when viewed from the first side S1 or the second side S2.

Hitherto, the embodiments of the present invention are described with reference to the drawings. However, these are just examples of the present invention, and various configurations other than the above may be employed.

For example, in the embodiment, when viewed from the direction perpendicular to the first surface 102 or the second surface 104, the plurality of first metal-containing layers 132 are in the shape of the islands which are separated from each other with the light-transmitting unit 144 interposed therebetween. However, when viewed from the direction perpendicular to the first surface 102 or the second surface 104, the plurality of first metal-containing layers 132 may be arranged in the stripe pattern.

This application claims priority from Japanese Patent Application No. 2021-005109, filed on Jan. 15, 2021, the disclosure of which is incorporated by reference in its entirety.

### REFERENCE SIGNS LIST

10 light-emitting device
100 substrate
102 first surface
104 second surface
110 first electrode
120 organic layer
122 electron injection layer
132 first metal-containing layer
134 metal compound-containing layer
136 second metal-containing layer
142 light-emitting unit
144 light-transmitting unit
150 cap layer
160 sealing unit
162 adhesive layer
170 desiccant
S1 first side
S2 second side

1. A light-emitting device comprising:
a substrate,
a first electrode having a light transmitting property located over the substrate,
an organic layer located over the first electrode,
a plurality of first metal-containing layers having a light shielding property located over the organic layer,
a metal compound-containing layer having a light transmitting property covering the plurality of first metal-containing layers, and
a second metal-containing layer having a light transmitting property covering the metal compound-containing layer.

2. The light-emitting device according to claim 1,
wherein each of the plurality of first metal-containing layers is surrounded by a light-transmitting unit.

3. The light-emitting device according to claim 2,
wherein a ratio of a width of each of the first metal-containing layers to a width of the light-transmitting unit between the first metal-containing layers adjacent to each other is equal to or greater than 0.50 and equal to or less than 1.7.

4. The light-emitting device according to claim 1,
wherein the metal compound-containing layer comprises
at least one selected from a group consisting of
molybdenum oxide, tungsten oxide, vanadium oxide, titanium oxide, tantalum oxide, rhenium oxide, and zinc sulfide.

5. The light-emitting device according to claim 1,
wherein the second metal-containing layer comprises at least one selected from a group consisting of silver, gold, and copper.

6. The light-emitting device according to claim 1,
wherein a thickness of the second metal-containing layer is equal to or greater than 6.0 nm and equal to or less than 15 nm.
